(19) United States
(12) Patent Application Publication
(10) Pub. No.: US 2011/0186113 A1
(43) Pub. Date: Aug. 4, 2011

(54) TERMINAL BOX FOR SOLAR CELL AND ATTACHING STRUCTURE

(76) Inventors: Hirofumi Nishi, Tokyo (JP); Katsumi Kushiya, Tokyo (JP)

(21) Appl. No.: 12/742,500

(22) PCT Filed: Nov. 11, 2008
(86) PCT No.: PCT/JP2008/070484

§ 371 Date: Jul. 23, 2010

(30) Foreign Application Priority Data
Nov. 16, 2007 (JP) 2007-297603

(51) Int. Cl. H01L 31/048; H01L 31/042

(52) U.S. Cl. 136/251; 136/244

(57) ABSTRACT

Provided are a terminal box, which protects a lead line of a frameless solar cell module from external moisture and the like and easily connects the solar cell modules to each other, and an attaching structure of a solar cell module having such a terminal box attached thereto. The terminal box is provided for a frameless solar cell having no frame for protecting a substrate glass and a cover glass from external forces. The terminal box is connected to an electrode for taking out power generated by receiving light, and a lead line for outputting the power to the outside is led out from an end portion of the solar cell module. The terminal box includes: a bonding section to be bonded to a side end portion of the solar cell module; an output terminal, which is electrically connected to the lead line to output the power obtained from the electrode of the solar cell module to the outside through the lead line; and a connecting section for connecting the terminal box to a prescribed external connector.

### TECHNICAL FIELD

The present invention relates to a terminal box to be attached to a solar cell module and an attaching structure of the terminal box.

### BACKGROUND ART

Conventionally, the terminal box for aggregating ribbon wires connected to an electrode of the solar cell module and leading out an output cable electrically connected to the ribbon wires is attached to a rear surface or the like of the solar cell module in order to output power generated by receiving solar light and the like to outside. In a case where a plurality of solar cell modules are arranged to form a solar cell array, the output cables of the adjacent solar cell modules are sequentially connected.

As an example of such solar cell module to which the conventional terminal box is attached, Patent Document 1 discloses the one in which lead lines of a positive electrode and a negative electrode of the solar cell are introduced into the terminal box arranged on a rear surface of a rear surface protecting member of the solar cell through a side surface portion of the rear surface protecting member to electrically connect the lead lines to an external connection cable.

On the other hand, in order to make solar cell module lighter and to reduce a manufacturing cost and the like, there is a frameless solar cell module having no frame attached, which sandwiches the solar cell by front and rear members such as glass.

As an example of such frameless solar cell module, Patent Document 2 discloses the solar cell module obtained by sequentially arranging a light-receiving surface side film, a light-receiving surface side filler, a plurality of solar cell devices electrically connected by means of a connection tab, a rear surface side filler and a rear surface side film in an overlapped manner and having a structure in which a peripheral edge portion of the light receiving surface side film and a peripheral edge portion of the rear surface side film are thermally fused.
Patent Document 1: Japanese Patent Application Laid-Open No. 2004-207463
Patent Document 2: Japanese Patent Application Laid-Open No. 2006-86390

### DISCLOSURE OF THE INVENTION

### Problem to be Solved by the Invention

As described above, it is necessary to allow the lead line led out from the electrode of the solar cell to go through the side surface portion of the rear surface protecting member in order to lead the same into the terminal box provided on the rear surface of the solar cell module. Especially, in a case of the frameless solar cell module, the lead line is exposed to the outside since there is no frame attached to the side surface, so that it is necessary to protect the lead line from water such as rain, physical pressure and the like by using the protecting member.

Also, when connecting the solar cell modules by extending the output cable from the terminal box, the output cables may get entangled, so that the one easy to connect and hardly getting entangled is required.

Therefore, an object of the present invention is to provide a terminal box capable of protecting the lead line from external moisture and the like and facilitating the connection of the solar cell modules, and an attaching structure of the solar cell module to which the terminal box is attached in the frameless solar cell module.

### Means for Solving the Problem

In order to achieve the above-described object, according to an aspect of the present invention, there is provided a terminal box for a frameless solar cell having no frame for protecting a substrate glass and a cover glass from external forces, wherein a lead line connected to an electrode for taking out power generated by receiving light and outputting the power to outside is led out from an end portion of a solar cell module, the terminal box including a bonding section to be bonded to a side end of the solar cell module, an output terminal electrically connected to the lead line for outputting the power obtained from the electrode of the solar cell module to the outside through the lead line, and a connecting section that connects to a prescribed external connector.

Also, the terminal box may have a hollow box shape, and may include an insertion hole for leading the lead line into the terminal box in the vicinity of the bonding section, and a deflector that bends the lead line on a side of the output terminal to guide the lead line into the terminal box.

Also, the connecting section may be detachably connected to the prescribed external connector.

Also, connection between the lead line and the output terminal may be made by allowing the lead line to connect to the output terminal from vertically above.

Also, connection between the lead line and the output terminal may be made by allowing the lead line to connect to the output terminal from vertically below.

Also, a lid for performing connecting operation of the lead line and the output terminal from outside of the terminal box may be provided on the terminal box.

Also, according to another aspect of the present invention, there is provided an attaching structure for constituting a solar cell array by connecting, side by side, a plurality of solar cell modules to which the terminal box for a solar cell is attached, wherein the terminal box for a solar cell is attached to a position from which a lead line of the solar cell module is led out by the bonding section.

Also, the solar cell modules may be obtained by stacking at least a substrate glass, a solar cell device formed on the substrate glass and a cover glass attached on a light receiving surface side of the solar cell device, and an edge space on which the solar cell device is not formed may be provided between an end portion of the solar cell device and an end portion of the substrate glass or an end portion of the cover glass, and the terminal box for a solar cell may be further attached to the solar cell module at the edge space portion by the bonding section.

Also, the lead line may be composed of a lead line corresponding to positive electrode connected to a positive electrode of the solar cell module and a lead line corresponding to negative electrode connected to a negative electrode of the solar cell module, the lead line corresponding to positive electrode and the lead line corresponding to negative electrode may be led out in directions opposite to each other from positions symmetrical with reference to a central portion of the solar cell module, and the terminal box for a solar cell may be further attached, by the bonding section, to the positions from which the lead line corresponding to positive electrode and the lead line corresponding to negative electrode are led out.

### Effect of the Invention

According to the present invention, it is possible to easily connect the solar cell modules while protecting the lead line led out from the solar cell module.

### BEST MODE FOR CARRYING OUT THE INVENTION

Next, a terminal box according to an embodiment of the present invention will be described with reference to the drawings.

FIG. 1 illustrates a solar cell formed by attaching a terminal box 1 according to a first embodiment of the present invention and a terminal box 2 according to a second embodiment of the present invention to solar cell modules 3 and 4. A position from which a lead line for deriving generated power to outside is led out is different between the solar cell module 3 in FIG. 1(a) and the solar cell module 4 in FIG. 1(b), and the terminal boxes 3 and 4 are attached so as to correspond to the position from which the lead line is led out.

Herein, both of the terminal boxes 1 and 2 include a configuration of the present invention and each of them is attached so as to correspond to any of a positive electrode and a negative electrode of the solar cell modules 3 and 4, and by connecting a connector included in the terminal box 1 and a connector included in the terminal box 2, a plurality of solar cell modules 3 and 4 may be connected in series.

Meanwhile, in this embodiment, the terminal box 1 is attached to the solar cell modules 3 and 4 so as to correspond to positive electrode output of the solar cell modules 3 and 4 and the terminal box 2 is attached to the solar cell modules 3 and 4 so as to correspond to negative electrode output of the solar cell modules 3 and 4.

First, the solar cell modules 3 and 4 to which the terminal boxes 1 and 2 are attached are described with reference to FIG. 2.

As illustrated in FIG. 2(a), the solar cell module 3 is composed of at least a substrate glass (not illustrated), a solar cell device 31 stacked on the substrate glass and a cover glass 32 to be attached on a light receiving surface of the solar cell device 31, and extraction electrodes (33a and 33b) for taking out the power generated by receiving light such as solar light to the outside are provided in the solar cell device 31.

Also, EVA resin is filled between the substrate glass and the cover glass 32 and a water-proof sealing material is appropriately applied on a stacked end face of the substrate glass and the cover glass 32.

Further, a frame-shaped edge space S on which the solar cell device 31 is not provided is formed on a position of an end portion of the substrate glass and the cover glass 32 of the solar cell module 3. In the edge space S, width X from an end portion of the solar cell device 31 to the end portion of the cover glass 32 becomes attaching width of the terminal boxes 1 and 2.

One of the extraction electrodes is the positive electrode (extraction positive electrode 33a) and the other of them is the negative electrode (extraction negative electrode 33b). A lead line corresponding to positive electrode 34a electrically connected to the extraction positive electrode 33a and a lead line corresponding to negative electrode 34b electrically connected to the extraction negative electrode 33b are led out from the stacked end faces on a transverse side of the solar cell module 3 to the outside. Herein, the lead line corresponding to positive electrode 34a and the lead line corresponding to negative electrode 34b are led out in directions opposite to each other from positions symmetrical with reference to a central portion of the solar cell module 3.

Meanwhile, a copper line plated with tin or other metal having a relatively low fusing point and the like may be used as the lead line corresponding to positive electrode 34a and the lead line corresponding to negative electrode 34b, for example.

A CIS-based thin film solar cell device is used as an example of the solar cell device 31. The CIS-based thin film solar cell device is a device formed by stacking thin films such as a metal rear surface electrode layer, a p-type light absorbing layer, a high-resistance buffer layer and an n-type window layer (transparent conductive film), and the solar cell device 31 generates power by receiving light such as solar light.

The solar cell module 4 illustrated in FIG. 2(b), as in the case of the solar cell module 3, also is composed of at least the substrate glass (not illustrated), a solar cell device 41 stacked on the substrate glass and a cover glass 42, and extraction electrodes (43a and 43b) for taking out power generated by receiving light such as solar light to the outside are provided in the solar cell device 41. One of the extraction electrodes is the positive electrode (extraction positive electrode 43a) and the other of them is the negative electrode (extraction negative electrode 43b). A lead line corresponding to positive electrode 44a electrically connected to the extraction positive electrode 43a and a lead line corresponding to negative electrode 44b electrically connected to the extraction negative electrode 43b are led out from positions symmetrical with reference to a central portion of the solar cell module 4 of the stacked end faces on the transverse side of the solar cell module 4 to the outside in directions opposite to each other.

Also, the frame-shaped edge space S on which the solar cell device 41 is not provided is formed on the position of the end portion of the substrate glass and the cover glass 42 of the solar cell module 4.

Meanwhile, the copper line plated with tin or other metal having a relatively low fusing point may be used also as the lead line corresponding to positive electrode 44a and the lead line corresponding to negative electrode 44b, for example, as in the case of the lead line corresponding to positive electrode 34a and the lead line corresponding to negative electrode 34b.

Herein, the lead line corresponding to positive electrode 34a and the lead line corresponding to negative electrode 34b in the solar cell module 3 and the lead line corresponding to positive electrode 44a and the lead line corresponding to negative electrode 44b in the solar cell module 4 are formed as follows. That is, the lead line corresponding to positive electrode 34a is led out to a position corresponding to the lead line corresponding to negative electrode 44b and the lead line corresponding to negative electrode 34b is led out to a position corresponding to the lead line corresponding to positive electrode 44a when forming a solar cell array 6 by alternately arranging the solar cell modules 3 and 4 so as to be adjacent to each other such that side end portions on the transverse side of them correspond to each other.

Next, the terminal box according to the embodiment of the present invention is described as follows.

FIGS. 3 and 4 illustrate the terminal box 1 according to the first embodiment of the present invention. The terminal box 1 is attached to the solar cell modules 3 and 4 to output the power generated in the solar cell modules 3 and 4 to the outside.

The terminal box 1 includes a connecter 11 for outputting the power from the solar cell modules 3 and 4 to the outside and a hollow box-shaped main body 12, as illustrated in FIGS. 3 and 4.

The connector 11 has a male structure having a male connecting terminal 111 on a central portion thereof and is covered with an exterior member formed of an insulating material such as synthetic resin. The connector 11 detachably male-female fits in a connector 21 of the terminal box 2, and in this state, the male connecting terminal 111 contacts a female connecting terminal 211, thereby electrically connecting the connector 11 to the connector 21.

The main body 12 is formed of an upper surface plate 12a, a front surface plate 12b, a side surface plate 12c, a pinching plate 12d, a rear surface plate 12e and a bottom surface plate 12f into a hollow box shape, and further includes a bonding section 13 to be bonded to the solar cell modules 3 and 4, an insertion hole 14 for leading the lead lines corresponding to positive electrode 34a and 44a led out from the solar cell modules 3 and 4 into the terminal box 1, a relay terminal 15 electrically connected to the male connecting terminal 111 and allowed to be connected to the lead lines corresponding to positive electrode 34a and 44a, thereby conducting the output from the solar cell modules 3 and 4 to the connector 11, and a deflector 16 for bending the lead lines corresponding to positive electrode 34a and 44a to lead the lead lines into the terminal box 1. The side surface plate 12c, the rear surface plate 12e or the bottom surface plate 12f may have a water-proof lid provided by means of a screw in order to facilitate operation to electrically connect the lead lines corresponding to positive electrode 34a and 44a and the relay terminal 15.

The main body 12 is integrally molded of resin such as plastic.

The upper surface plate 12a has a gap for sandwiching the solar cell modules 3 and 4 between a rear surface thereof and the pinching plate 12d, and the gap constitutes the bonding section 13 for sandwiching the solar cell modules 3 and 4 to bond to the terminal box 1.

An attaching hole for attaching the connector 11 is provided on the front surface plate 12b.

The side surface plate 12c has a portion with horizontal width D and a portion wider than the horizontal width D by X′. The horizontal width D is provided for providing the insertion hole 14 for leading the lead lines 34a, 34b, 44a and 44b into the main body 12 and for attaching the deflector 16, and this width is preferably short in order to reduce a gap between the adjacent solar cell modules 3 and 4 when connecting a plurality of solar cell modules 3 and 4. Also, X′ becomes attaching width of the solar cell modules 3 and 4 and, by making X′ equal to or shorter than the width X of the edge space S of the solar cell modules 3 and 4, the terminal box 1 may be attached only to the edge space S portion, so that the terminal box 1 does not shadow the portion of the solar cell device 31 to deteriorate power generating efficiency.

Meanwhile, by making thickness of the gap formed by the upper surface plate 12a and the pinching plate 12d equal to or slightly larger than the thickness of the solar cell modules 3 and 4, the solar cell modules 3 and 4 may be fitted into the bonding section 13 without a gap and bonded.

The bonding section 13 is composed of the upper surface plate 12a, the side surface plate 12c and the pinching plate 12d of the main body 12 as a gap in a C-shape in cross section. When inserting the solar cell modules 3 and 4 into the bonding section 13, the end face of the solar cell modules 3 and 4 abuts an end face of a portion with the horizontal width D of the side surface plate 12c, and the solar cell modules 3 and 4 are pinched by the upper surface plate 12a and the pinching plate 12d to be fitted thereinto without a gap. As a result, the terminal box 1 is attached to the solar cell modules 3 and 4.

Meanwhile, when bonding the solar cell modules 3 and 4 to the bonding section 13, abutting surfaces of the terminal box 1 and the solar cell modules 3 and 4 may be bonded by a prescribed bonding adhesive and the like, thereby preventing moisture from entering the terminal box 1.

The insertion hole 14 is a hole penetrating from the bonding section 13 into the terminal box 1. The lead lines corresponding to positive electrode 34a and 44a led out from the solar cell modules 3 and 4 are led into the terminal box 1 through the insertion hole 14.

Meanwhile, the insertion hole 14 may have a size or a shape allowing the lead lines corresponding to positive electrode 34a and 44a to pass therethrough. Also, when bonding the solar cell modules 3 and 4 to the bonding section 13, the solar cell modules 3 and 4 are pinched by the upper surface plate 12a and the pinching plate 12d and abut the end face of the portion with the horizontal width D of the side surface plate 12c, so that the insertion hole 14 is blocked from the outside and it is possible to prevent water and the like from entering the terminal box 1 from the outside through the insertion hole 14.

The relay terminal 15 has a shape obtained by bending a narrow thin plate formed of a conductive material and is composed of an inner bottom portion 15a connected to an inner bottom portion of the terminal box 1 and an upright portion 15b connected to the male connecting terminal 111 of the connector 11. In the relay terminal 15, the lead lines corresponding to positive electrode 34a and 44a led out from the solar cell modules 3 and 4 are connected to the inner bottom portion 15a by means of soldering or the like, and the lead lines corresponding to positive electrode 34a and 44a are electrically connected to the connector 11 through the upright portion 15b.

For this soldering operation, a detachable water-proof lid may be provided on the side surface plate 12c, the rear surface plate 12e or the bottom plate 12f by means of the screw.

The deflector 16 is a thin plate having an arc shape with a gradual in cross section. The deflector 16 is attached in the terminal box 1 such that an inner peripheral surface thereof faces a side of the solar cell modules 3 and 4 when attaching the terminal box 1 to the solar cell modules 3 and 4. In a state in which the terminal box 1 is attached to the solar cell modules 3 and 4, the lead lines corresponding to positive electrode 34a and 44a abut the inner peripheral surface of the deflector 16, thereby being bent in a direction of the insertion hole 14 to be led into the terminal box 1 and further guided to the relay terminal 15.

Also, the deflector 16 is formed of an electrically insulating material or a surface thereof is covered with an electrically insulating film, and has sufficient heat resistance properties and chemical stability. The deflector 16 may be formed integrally with the main body 12.

FIGS. 5 and 6 illustrate the terminal box 2 according to the second embodiment of the present invention. The terminal box 2 is attached to the solar cell modules 3 and 4 for outputting the power generated in the solar cell modules 3 and 4 to the outside.

The terminal box 2 has a hollow box shape and is composed of the connector 21 for outputting current from the solar cell modules 3 and 4 to the outside and a main body 22 in a hollow box shape, as illustrated in FIGS. 5 and 6.

The main body 22 is formed of an upper surface plate 22a, a front surface plate 22b, a side surface plate 22c, a pinching plate 22d, a rear surface plate 22e and a bottom surface plate 22f into a hollow box shape, and further includes a bonding section 23 for bonding to the solar cell modules 3 and 4, an insertion hole 24 for leading the lead lines corresponding to negative electrode 34b and 44b led out from the solar cell modules 3 and 4 into the terminal box 2, a relay terminal 25 connected to the lead lines corresponding to negative electrode 34b and 44b and the connector 11 to conduct the output of the solar cell modules 3 and 4 to the connector 21, and a deflector 26 for bending the lead lines corresponding to negative electrode 34b and 44b to lead the lead lines into the terminal box 2. The water-proof lid may be provided by means of the screw on the side surface plate 22c, the rear surface plate 22e or the bottom surface plate 22f in order to facilitate the operation to electrically connect the lead lines corresponding to positive electrode 34a and 44a and the relay terminal 25.

The main body 22 is integrally molded of resin such as plastic.

Meanwhile, the main body 22, the bonding section 23, the insertion hole 24, the relay terminal 25 and the deflector 26 constituting the terminal box 2 correspond to the main body 12, the bonding section 13, the insertion hole 14, the relay terminal 15 and the deflector 16, respectively, of the terminal box 1 and have similar configurations.

Also, the terminal box 2 is attached so as to correspond to the negative electrode of the solar cell modules 3 and 4, and the lead lines corresponding to negative electrode 34b and 44b led out from the solar cell modules 3 and 4 are led into the terminal box 2 through the insertion hole 24 to be connected to the relay terminal 25 by means of soldering or the like, and further, electrically connected to the connector 21 through the relay terminal 25. Meanwhile, as in the case of the terminal box 1, the lead lines corresponding to negative electrode 34b and 44b abut the inner peripheral surface of the deflector 26 and are bent in a direction of the insertion hole 24 to be led into the terminal box 1. For the soldering operation, the detachable water-proof lid capable of being fixed by the screw may be provided on the side surface plate 22c, the rear surface plate 22e or the bottom surface plate 22f.

The connector 21 has a female structure having the female connecting terminal 211 on the central portion thereof and is covered with an exterior member made of an insulating material such as synthetic resin. The connector 21 detachably male-female fits in the connector 11 of the terminal box 1, and in this state, the male connecting terminal 111 and the female connecting terminal 211 contact each other, thereby electrically connecting the connector 11 and the connector 21.

Subsequently, a process of attaching the terminal boxes 1 and 2 to the solar cell modules 3 and 4 and an attached state will be described with reference to FIGS. 7 and 8.

First, in the process of attaching the terminal box 1 to the solar cell module 3, as illustrated in FIG. 7(a), the terminal box 1 is attached to a position from which the lead line corresponding to positive electrode 34a is led out of the solar cell module 3.

At the time of attaching, as illustrated in FIG. 9(a), the solar cell module 3 is fitted in the bonding section 13, and the lead line corresponding to positive electrode 34a, which abuts the deflector 16 to be bent in a direction of the relay terminal 15, is led into the terminal box 1 through the insertion hole 14 and is soldered to the inner bottom portion 15a of the relay terminal 15. As a result, the power derived from the lead line corresponding to positive electrode 34a is conducted from the inner bottom portion 15a through the upright portion 15b to the male connecting terminal 111.

Meanwhile, when soldering the lead line corresponding to positive electrode 34a to the inner bottom portion 15a of the relay terminal 15, the soldering is performed by opening the lid provided in advance on the side surface plate 12c, the rear surface plate 12e or the bottom surface plate 12f, after which the lid is closed.

Subsequently, as in the case of the terminal box 1, the terminal box 2 is attached to a position from which the lead line corresponding to negative electrode 34b is led out of the solar cell module 3. At the time of attaching, as illustrated in FIG. 9(b), the solar cell module 3 is fitted in the bonding section 23, and the lead line corresponding to negative electrode 34b, which abuts the deflector 26 to be bent in a direction of the rely terminal 25, is led into the terminal box 2 through the insertion hole 24 and is soldered to an inner bottom portion 25a of the relay terminal 25. As a result, the power derived from the lead line corresponding to negative electrode 34b is conducted from the inner bottom portion 25a through the upright portion 25b to the female connecting terminal 211.

Meanwhile, also when soldering the lead line corresponding to negative electrode 34b to the inner bottom portion 25a of the relay terminal 25, as in the case of the terminal box 1, the soldering is performed by opening the lid provided in advance on the side surface plate 22c, the rear surface plate 22e or the bottom surface plate 22f, after which the lid is closed.

In the above-described manner, in the state in which the terminal boxes 1 and 2 are attached to the solar cell module 3, the lead line corresponding to positive electrode 34a and the lead line corresponding to negative electrode 34b are guided to positions at which the relay terminals 15 and 25 are attached by the deflectors 16 and 26, respectively, so that the lead line corresponding to positive electrode 34a and the lead line corresponding to negative electrode 34b do not contact an inner wall or the like of the terminal boxes 1 and 2 and do not get entangled with each other.

Also, the solar cell module 3 is bonded to the bonding section 13 only in the portion of the edge space S and the portion of the solar cell device 31 is not hidden by the terminal boxes 1 and 2, so that the power generating efficiency is not deteriorated.

Attachment of the terminal boxes 1 and 2 to the solar cell module 4 is performed as in the case of the solar cell module 3. That is, as illustrated in FIGS. 8(a) and 8(b), the terminal box 1 is attached to a position from which the lead line corresponding to positive electrode 44a is led out of the solar cell module 4 and the terminal box 2 is attached to a position from which the lead line corresponding to negative electrode 44b is led out of the solar cell module 4.

A plurality of the solar cell modules 3 and 4 to which the terminal boxes 1 and 2 are attached may be connected such that they are alternately adjacent to each other as illustrated in FIG. 10, thereby forming the solar cell array 6 illustrated in FIG. 11.

The solar cell modules 3 and 4 are connected to each other by male-female fitting of the female connector 21 of the terminal box 2 attached to the solar cell module 3 and the male connector 11 of the terminal box 1 attached to the solar cell module 4 or by the male-female fitting of the male connector 11 of the terminal box 1 attached to the solar cell module 3 and the female connector 21 of the terminal box 2 attached to the solar cell module 4.

The solar cell modules 3 and 4 thus connected are electrically connected to each other by contact of the male connecting terminal 111 and the female connecting terminal 211, and all of the connected solar cell modules 3 and 4 are connected in series.

Then, as illustrated in FIG. 11, by installing a group of solar cell modules connected in series obtained by alternately connecting the solar cell modules 3 and 4 on a prescribed supporting structure 5, the solar cell array 6 may be formed.

In this manner, by using the terminal boxes 1 and 2, even with the frameless solar cell module, the solar cell modules may be easily connected to each other while protecting the lead line. Also, it is not necessary to use a sheet for protecting the lead line, an output cable or the like, so that a light-weight solar cell module with a reduced cost may be realized.

Meanwhile, the terminal box 1 is electrically connected to the positive electrode of the solar cell modules 3 and 4 and the terminal box 2 is electrically connected to the negative electrode of the solar cell modules 3 and 4 in the above-described embodiment. On the contrary, the terminal box 1 may be electrically connected to the negative electrode of the solar cell modules 3 and 4 and the terminal box 2 may be electrically connected to the positive electrode of the solar cell modules 3 and 4, and an arbitrary configuration is possible.

Also, although a shape and a connecting method of the connectors 11 and 21 are by the male-female fitting in this embodiment, there is no limitation and another configuration is possible as long as they may be electrically connected.

Also, the relay terminal 15 and the male connecting terminal 111 or the relay terminal 25 and the female connecting terminal 211 may be integrally formed, and the relay terminal 15 may be formed as a part of the connector 11 or the relay terminal 25 may be formed as a part of the connector 21.

Next, a terminal box 7 according to a third embodiment of the present invention and a terminal box 8 according to a fourth embodiment of the present invention will be described with reference to FIG. 12. Meanwhile, the following description is made based on a state in which the terminal boxes 7 and 8 according to this embodiment are attached to the solar cell module 3.

FIG. 12(a) illustrates the terminal box 7 according to the third embodiment. The terminal box 7 is a modification of the terminal box 1 and is composed of the connector 11 and a main body 72 formed into a hollow box shape, and the main body 72 includes the bonding section 13, the insertion hole 14, a relay terminal 75 and the deflector 16.

Meanwhile, configurations of the connector 11, the bonding section 13, the insertion hole 14 and the deflector 16 are similar to those of the terminal box 1. Also, an upper surface plate 72a, a front surface plate 72b, a side surface plate (not illustrated), a pinching plate 72d, a rear surface plate 72e and a bottom surface plate 72f constituting the main body 72 correspond to the upper surface plate 12a, the front surface plate 12b, the side surface plate 12c, the pinching plate 12d, the rear surface plate 12e and the bottom surface plate 12f of the terminal box 1, respectively, and have the similar configurations.

The relay terminal 75 is similar to the relay terminal 15 in that it is formed of the conductive material and is installed in the terminal box 1, and that the lead line corresponding to positive electrode 34a led out from the solar cell module 3 is connected by means of soldering or the like and is electrically connected to the connector 11. Unlike the relay terminal 15, however, the relay terminal 75 has a substantially C-shape in cross section, as illustrated in FIG. 12(a).

The relay terminal 75 is composed of a lower surface portion 75a horizontally provided in the terminal box 1, an upright portion 75b connected to the male connecting terminal 111 of the connector 11, an upper surface portion 75c horizontally provided on a rear surface side of the pinching plate 72d and a joining section 75d for joining the lower surface portion 75a with the upper surface portion 75c. The lead line corresponding to positive electrode 34a may be attached to the upper surface portion 75c from below vertically upward in a space enclosed by the lower surface portion 75a, the upper surface portion 75c and the joining section 75d.

As a result, dust is not accumulated on an attaching position by soldering of the relay terminal 75 and the lead line corresponding to positive electrode 34a, and if by any chance water enters, the water is not accumulated on the attaching position, so that defect and the like on the attaching position may be prevented. Meanwhile, in order to facilitate the operation to electrically connect the lead lines corresponding to positive electrode 34a and 44a and the relay terminal 75, the water-proof lid may be provided by means of the screw on the side surface plate or the bottom surface plate 72f.

The main body 72 is integrally molded of resin such as plastic.

On the other hand, the terminal box 8 illustrated in FIG. 12(b) is a modification of the terminal box 2, and is composed of the connector 21 having the configuration similar to that of the terminal box 2 and a main body 82 formed into a hollow box shape. The main body 82 includes the bonding section 23, the insertion hole 24 and the deflector 26, and further includes a relay terminal 85 having the configuration similar to that of the relay terminal 75 of the terminal box 7.

Meanwhile, configurations of the connector 21, the bonding section 23, the insertion hole 24 and the deflector 26 are similar to those of the terminal box 2. Also, an upper surface plate 82a, a front surface plate 82b, a side surface plate (not illustrated), a pinching plate 82d, a rear surface plate 82e and a bottom surface plate 82f constituting the main body 82 correspond to the upper surface plate 22a, the front surface plate 22b, the side surface plate 22c, the pinching plate 22d, the rear surface plate 22e and the bottom surface plate 22f of the terminal box 2, respectively, and have the similar configurations.

The relay terminal 85 is composed of a lower surface portion 85a horizontally provided in the terminal box 1, an upright portion 85b connected to the female connecting terminal 211 of the connector 21, an upper surface portion 85c provided horizontally on a rear surface side of the pinching plate 82d and a joining section 85d joining the lower surface portion 85a with the upper surface portion 85c. The lead line corresponding to negative electrode 34b may be attached to the upper surface portion 85c from below vertically upward in a space enclosed by the lower surface portion 85a, the upper surface portion 85c and the joining section 85d. Meanwhile, as in the case of the terminal box 7, in order to facilitate the operation to electrically connect the lead lines corresponding to negative electrode 34b and 44b and the relay terminal 85, the water-proof lid may be provided by means of the screw on the side surface plate or the bottom surface plate 82f.

The main body 82 is integrally molded of resin such as plastic.

Meanwhile, as for the terminal boxes 7 and 8 of this embodiment, only the example in which they are attached to the solar cell module 3 has been described. As in the case of the terminal boxes 1 and 2, however, they may be also attached to the solar cell module 4, and as a result, the solar cell array may be formed by connecting a plurality of the solar cell modules 3 to which the terminal boxes 7 and 8 are attached and a plurality of the solar cell modules 4 to which the terminal boxes 7 and 8 are attached side by side.

Meanwhile, in this example also, the terminal box 7 may be electrically connected to the negative electrode of the solar cell modules 3 and 4 and the terminal box 8 may be electrically connected to the positive electrode of the solar cell modules 3 and 4.

Next, a terminal box 9 according to a fifth embodiment of the present invention will be described with reference to FIG. 13.

As illustrated in FIG. 13, the terminal box 9 is a modification of the terminal box 1 and is composed of the connector 11 and a main body 92 in a hollow box shape. The main body 92 includes a bonding section, an insertion hole and a deflector (all of them are not illustrated) corresponding to the bonding section 13, the insertion hole 14 and the deflector 16 of the terminal box 1 and having the similar configurations in addition to the relay terminal 95, and further the main body 92 is composed of an upper surface plate, a front surface plate, a side surface plate, a pinching plate, a rear surface plate and a bottom surface plate (not illustrated) corresponding to the upper surface plate 12a, the front surface plate 12b, the side surface plate 12c, the pinching plate 12d, the rear surface plate 12e and the bottom surface plate 12f and having the similar configurations.

The main body 92 is integrally molded of resin such as plastic.

The relay terminal 95 is similar to the relay terminal 15 in that it is formed of the conductive material and is installed in the terminal box 1, and that the lead line corresponding to positive electrode 34a led out from the solar cell module 3 is connected by means of soldering or the like and is electrically connected to the connector 11. However, the relay terminal 95 has a form different from that of the relay terminal 15, as illustrated in FIG. 13.

The relay terminal 95 is composed of a front surface portion 95a connected to the male connecting terminal 111 of the connector 11, a side surface portion 95b abutting an inner wall of the side surface plate, a rear surface portion 95c abutting an inner wall of the rear surface plate and an upper surface portion 95d parallel to the bottom surface plate, which are integrally formed. The lead line corresponding to positive electrode 35a may be attached to a lower surface of the upper surface portion 95d from below vertically upward.

Also, the relay terminal 95 may be fixedly attached in the terminal box 9 by fixing the side surface portion 95b to the side surface plate by means of the screw.

Further, the water-proof lid may be provided by means of the screw on the bottom surface plate in order to facilitate the operation to electrically connect the lead line corresponding to positive electrode 34a and the relay terminal 95. Since a structure is such that the lid is provided on the bottom surface plate and the lead line corresponding to positive electrode 35a is attached to the lower surface of the upper surface portion 95d, when soldering the lead line corresponding to positive electrode 35a to the relay terminal 95, a soldering iron may be put in the terminal box 9 straight and the solar cell module 3 does not get in the way of the same when the soldering iron is tilted, so that the soldering operation is easy.

Meanwhile, although the example in which the terminal box 9 is attached to the solar cell module 3 has been described in this embodiment, the terminal box 9 may also be attached to the solar cell module 4 as in the case of the terminal box 1.

Also, although only the terminal box 9 corresponding to the modification of the terminal box 1, that is, the terminal box 9 having the male connector 11 has been described in this embodiment, the terminal box corresponding to the modification of the terminal box 2 may be composed by composing the connector 11 as the female connector 21.

### BRIEF DESCRIPTION OF THE DRAWINGS

FIG. 1 is a front perspective view illustrating an appearance of a solar cell to which a terminal box according to an embodiment of the present invention is attached.

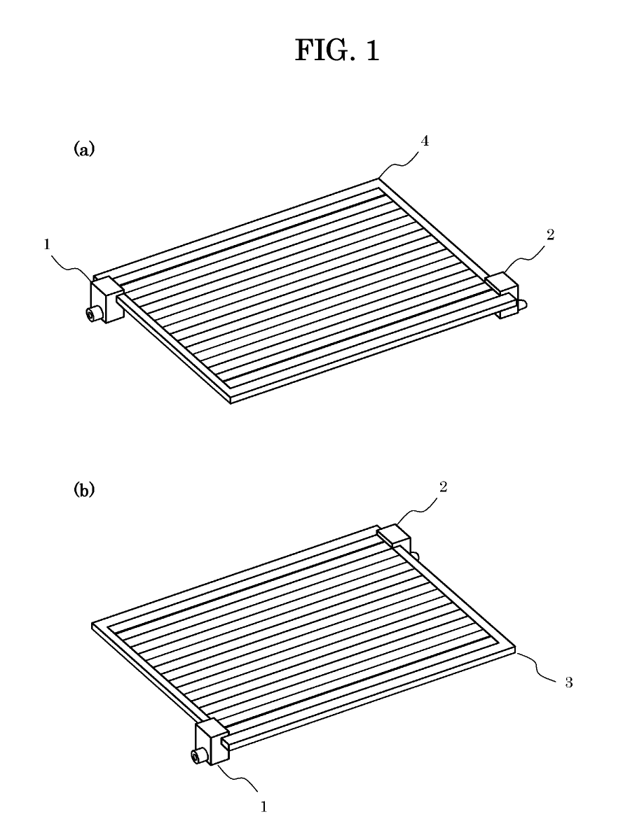

FIG. 2 is a front view illustrating an example of a solar cell module to which the terminal box according to this embodiment is attached, wherein (a) illustrates an example of the solar cell module in which a lead line connected to an electrode is led out from a prescribed position of an end portion and (b) illustrates an example of the solar cell module in which the lead line connected to the electrode is led out from a position of the end portion different from that in (a).

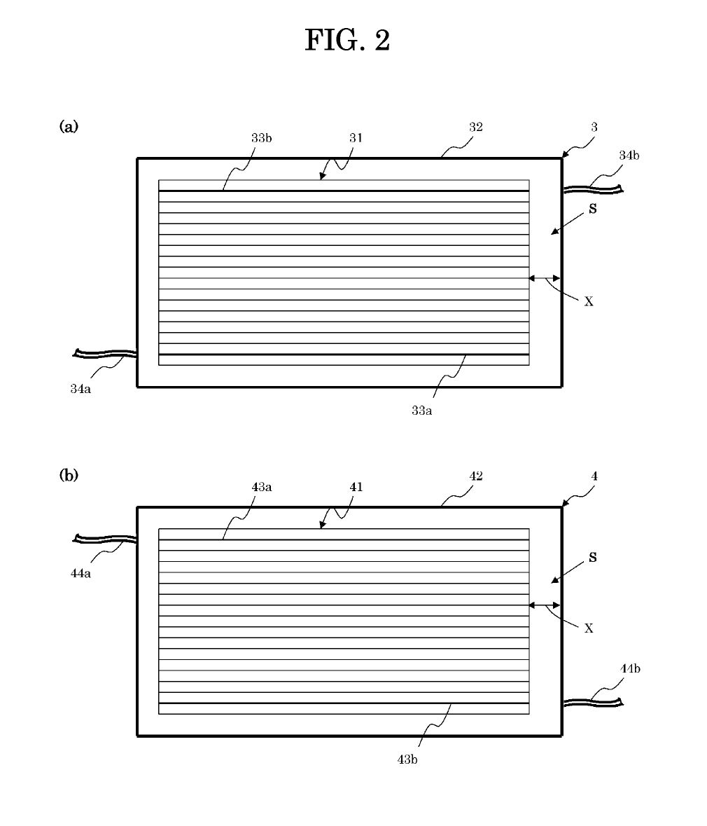

FIG. 3 is a view illustrating the appearance of a terminal box according to a first embodiment of the present invention, wherein (a) is a front perspective view and (b) is a back perspective view.

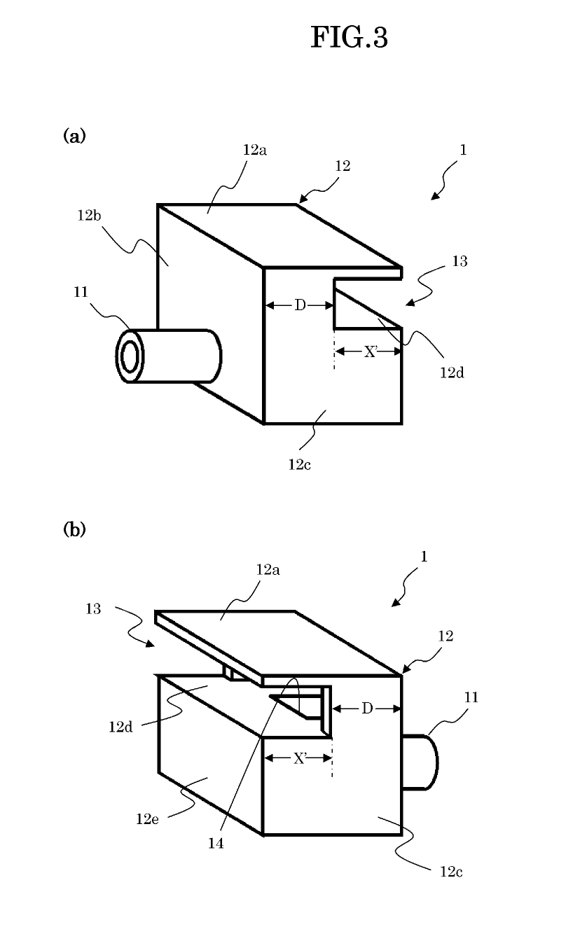

FIG. 4 is a cross-sectional view illustrating the terminal box according to this embodiment.

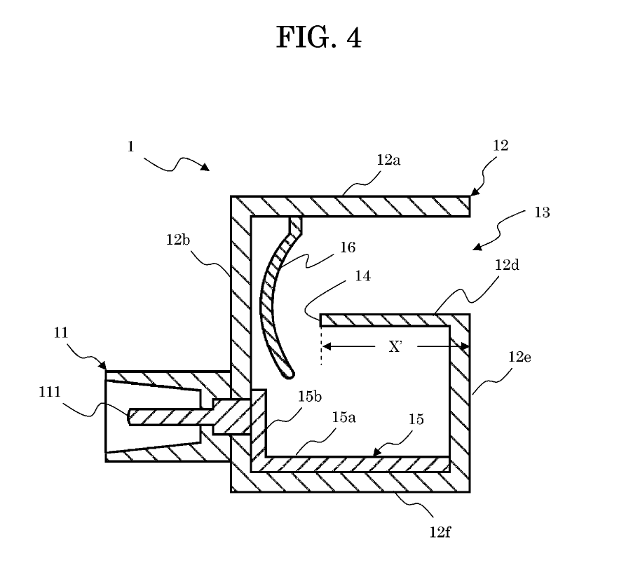

FIG. 5 is a view illustrating the appearance of a terminal box according to a second embodiment of the present invention, wherein (a) is a front perspective view and (b) is a back perspective view.

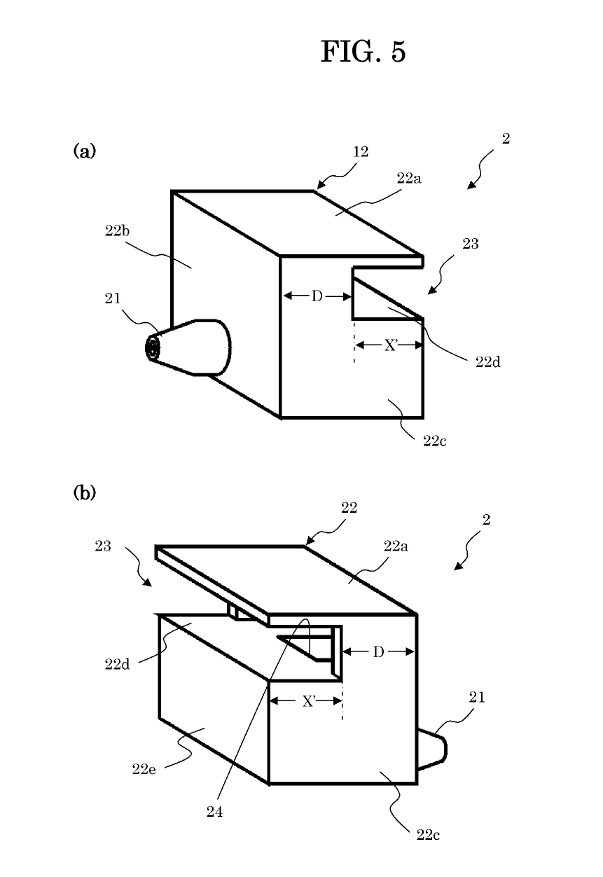

FIG. 6 is a cross-sectional view illustrating the terminal box according to this embodiment.

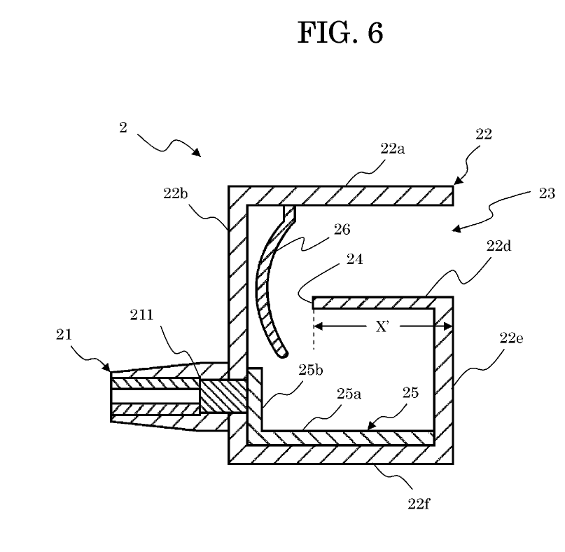

FIG. 7 is a view for illustrating an example in which the terminal box according to the first and second embodiments is attached to the solar cell module, wherein (a) is a front perspective view and (b) is a back perspective view.

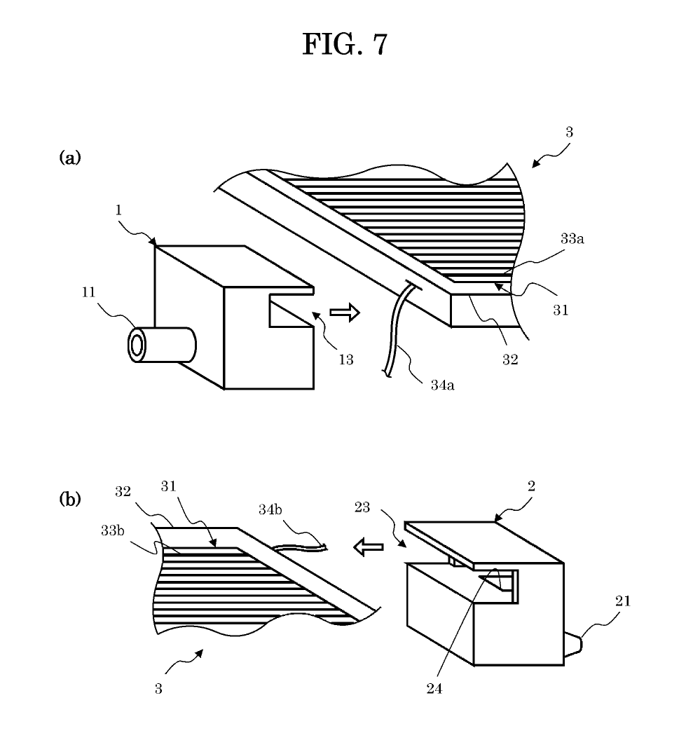

FIG. 8 is a view for illustrating another example in which the terminal box according to the first and second embodiments is attached to the solar cell module, wherein (a) is a front perspective view and (b) is a back perspective view.

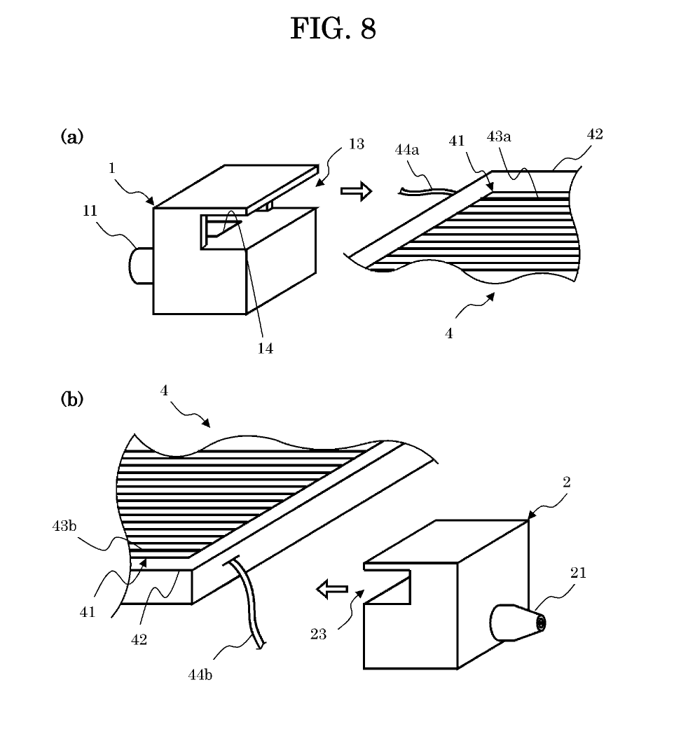

FIG. 9(a) is a cross-sectional view illustrating a state in which the terminal box according to the first embodiment is attached to the solar cell module, and FIG. 9(b) is a cross-sectional view illustrating a state in which the terminal box according to the second embodiment is attached to the solar cell module.

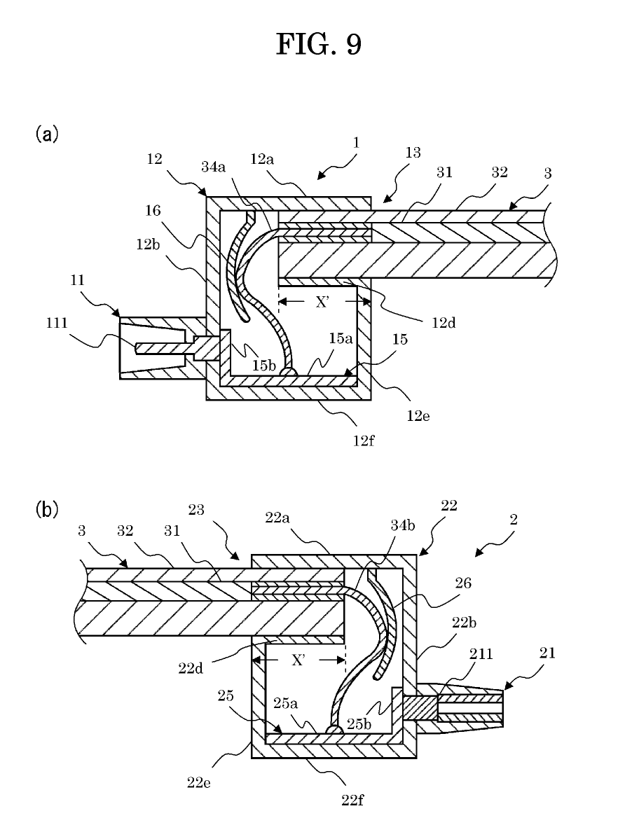

FIG. 10 is a front perspective view for illustrating a case of bonding the solar cell modules to which the terminal boxes according to the first and second embodiments are attached.

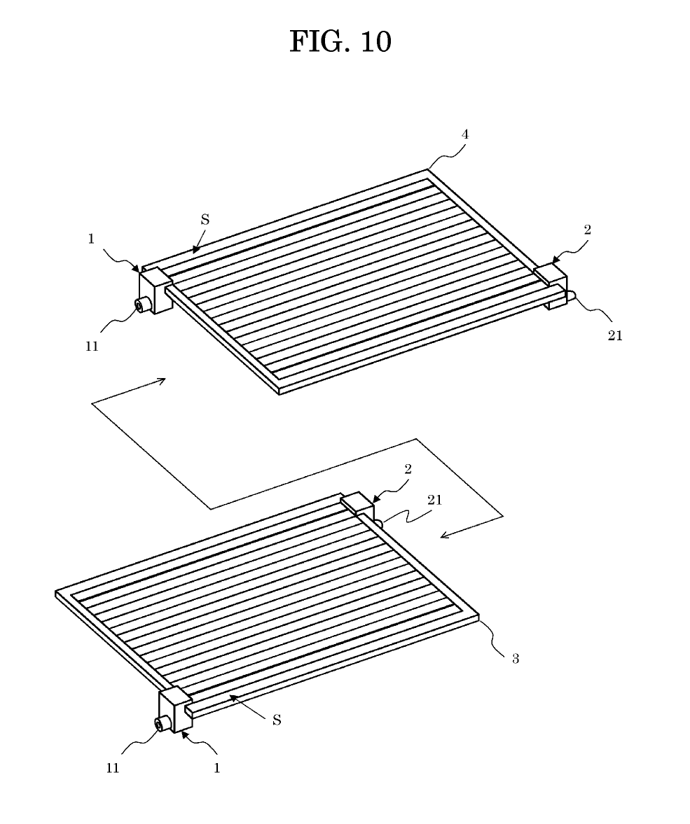

FIG. 11 is a front view illustrating a solar cell array obtained by bonding the solar cell modules to which the terminal boxes according to the first and second embodiments are attached.

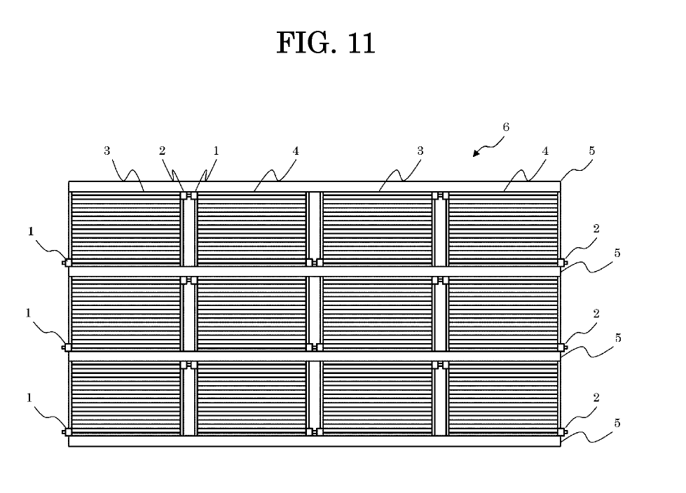

FIG. 12(a) is a cross-sectional view illustrating a state in which a terminal box according to a third embodiment is attached to the solar cell module, and FIG. 12(b) is a cross-sectional view illustrating a state in which a terminal box according to a fourth embodiment is attached to the solar cell module.

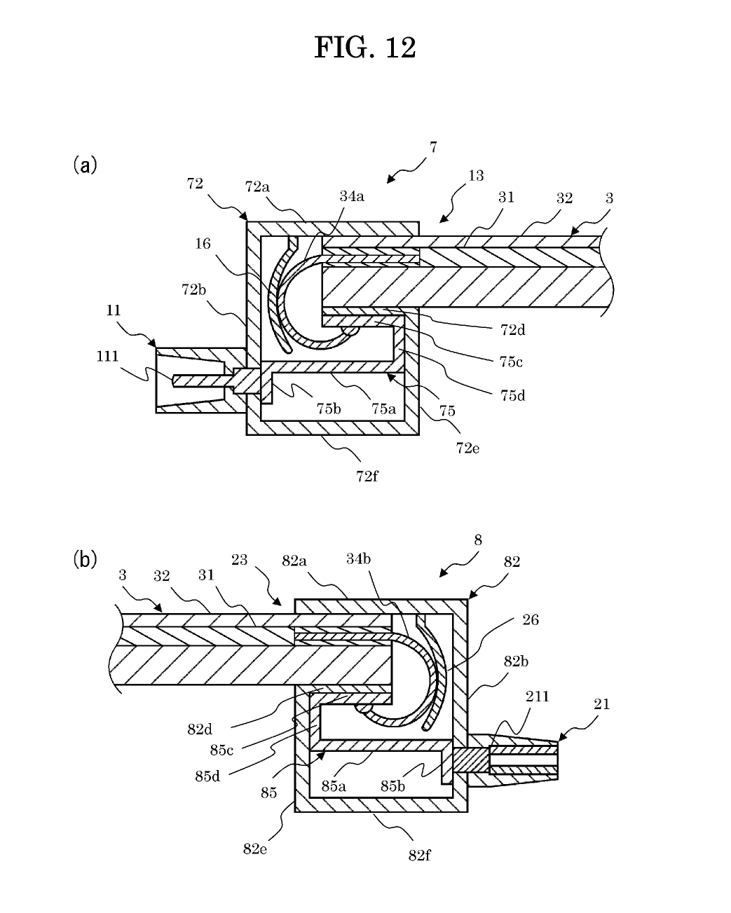

FIG. 13 is a perspective view illustrating a shape of a relay terminal in a terminal box according to a fifth embodiment.

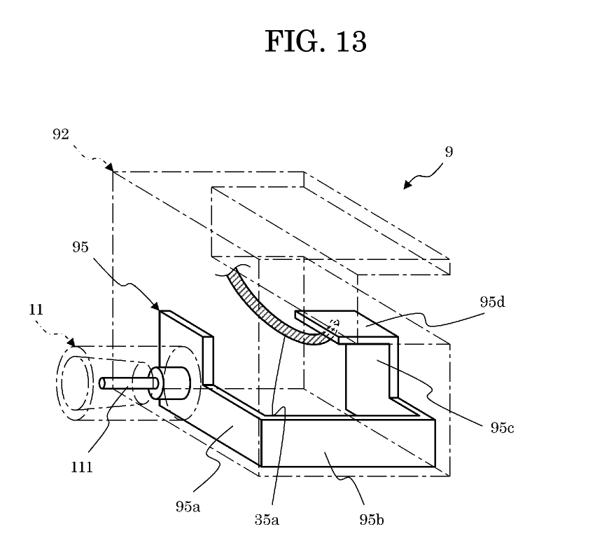

### DESCRIPTION OF LETTERS AND NUMERALS

1 terminal box
11 connector
111 male connecting terminal
12 main body
13 bonding section
14 insertion hole
15 relay terminal
16 deflector
2 terminal box
21 connector
211 female connecting terminal
22 main body
23 bonding section
24 insertion hole
25 relay terminal
26 deflector
3 solar cell module
31 solar cell device
32 cover glass
33a extraction positive electrode
33b extraction negative electrode
34a lead line corresponding to positive electrode
34b lead line corresponding to negative electrode
4 solar cell module
41 solar cell device
42 cover glass
43a extraction positive electrode
43b extraction negative electrode
44a lead line corresponding to positive electrode
44b lead line corresponding to negative electrode
5 supporting structure
6 solar cell array
7 terminal box
72 main body
75 relay terminal
8 terminal box
82 main body
85 relay terminal
9 terminal box
92 main body
95 relay terminal
S edge space

1. A terminal box for a frameless solar cell having no frame for protecting a substrate glass and a cover glass from external forces, wherein a lead line connected to an electrode for taking out power generated by receiving light and outputting the power to outside is led out from an end portion of a solar cell module, the terminal box comprising:
a bonding section to be bonded to a side end of the solar cell module;
an output terminal electrically connected to the lead line for outputting the power obtained from the electrode of the solar cell module to the outside through the lead line; and
a connecting section that connects to a prescribed external connector.

2. The terminal box for a solar cell according to claim 1, wherein
the terminal box has a hollow box shape, and includes:
an insertion hole for leading the lead line into the terminal box in the vicinity of the bonding section; and
a deflector that bends the lead line on a side of the output terminal to guide the lead line into the terminal box.

3. The terminal box for a solar cell according to claim 1, wherein
the connecting section is detachably connected to the prescribed external connector.

4. The terminal box for a solar cell according to claim 1, wherein connection between the lead line and the output terminal is made by allowing the lead line to connect to the output terminal from vertically above.

5. The terminal box for a solar cell according to claim 1, wherein connection between the lead line and the output terminal is made by allowing the lead line to connect to the output terminal from vertically below.

6. The terminal box for a solar cell according to claim 1, wherein
a lid for performing connecting operation of the lead line and the output terminal from outside of the terminal box is provided on the terminal box.

7. An attaching structure for constituting a solar cell array by connecting, side by side, a plurality of solar cell modules to which the terminal box for a solar cell according to claim 1 is attached, wherein
the terminal box for a solar cell is attached to a position from which a lead line of the solar cell module is led out by the bonding section.

8. The attaching structure according to claim 7, wherein
the solar cell modules is obtained by stacking at least a substrate glass, a solar cell device formed on the substrate glass and a cover glass attached on a light receiving surface side of the solar cell device, and an edge space on which the solar cell device is not formed is provided between an end portion of the solar cell device and an end portion of the substrate glass or an end portion of the cover glass, and
the terminal box for a solar cell is further attached to the solar cell module at the edge space portion by the bonding section.

9. The attaching structure according to claim 7, wherein
the lead line is composed of a lead line corresponding to positive electrode connected to a positive electrode of the solar cell module and a lead line corresponding to negative electrode connected to a negative electrode of the solar cell module,
the lead line corresponding to positive electrode and the lead line corresponding to negative electrode are led out in directions opposite to each other from positions symmetrical with reference to a central portion of the solar cell module, and
the terminal box for a solar cell is further attached, by the bonding section, to the positions from which the lead line corresponding to positive electrode and the lead line corresponding to negative electrode are led out.
